(19) United States
(12) Patent Application Publication
(10) Pub. No.: US 2012/0161578 A1
(43) Pub. Date: Jun. 28, 2012

(54) METHOD OF DRIVING PIEZOELECTRIC DEVICE

(75) Inventors: Akira Shimada, Kawasaki-shi (JP); Kaishi Ohashi, Tokyo (JP)

(73) Assignee: CANON KABUSHIKI KAISHA, Tokyo (JP)

(21) Appl. No.: 13/306,495

(22) Filed: Nov. 29, 2011

(30) Foreign Application Priority Data
Dec. 24, 2010 (JP) 2010-287491

(51) Int. Cl. H01L 41/09

(52) U.S. Cl. 310/317

(57) ABSTRACT

Provided is a method of driving a piezoelectric device including a piezoelectric material having at least two phase transition temperatures and is polarized in one of thickness directions, and electrodes disposed on both end surfaces of the piezoelectric material in a direction orthogonal to the polarized direction, the method including: applying an alternating electric field to the piezoelectric device by an electric field applying unit; and applying a bias electric field in accordance with a variation of a coercive electric field due to temperature variation so that an absolute value of an electric field in a direction opposite to the polarized direction in the alternating electric field applied by the electric field applying unit becomes smaller than the coercive electric field and so that a polarization of the piezoelectric material is not reversed by the electric field in the direction opposite to the polarized direction.

### BACKGROUND OF THE INVENTION

1. Field of the Invention

The present invention relates to a method of driving a piezoelectric device, and more particularly, to a method of driving a piezoelectric device that can be applied appropriately to an ultrasonic motor, a foreign substance removing apparatus (a dust removing apparatus), utilizing ultrasonic oscillation.

2. Description of the Related Art

Lead titanate zirconate has been mainly used as a piezoelectric material to be an oscillation excitation source of a piezoelectric actuator utilizing an oscillation displacement of an ultrasonic motor, a foreign substance removing apparatus (a dust removing apparatus), and the like.

However, along with an increasing awareness of environment, development of a non-lead piezoelectric material that does not contain lead is in progress.

One of such non-lead piezoelectric materials, there is a barium titanate-based material.

Barium titanate has a relatively high piezoelectric constant among non-lead piezoelectric materials. However, barium titanate has four phase transition temperatures, and one of them is close to room temperature at which a crystal structure changes from an orthorhombic to a tetragonal when changing from low temperature to high temperature.

Therefore, at this temperature, the piezoelectric constant becomes a maximum value and changes significantly by a slight change of temperature.

Therefore, when a non-lead-based piezoelectric material such as barium titanate is used for a piezoelectric device, there is a problem in that a displacement becomes significantly deviated from a desired amount by a slight change of temperature at a temperature close to the phase transition temperature.

When an electric field of a predetermined strength or larger is applied to the polarized piezoelectric material in the opposite direction to the polarization, a sign of the polarization is reversed (namely, the direction of the polarization is reversed). The electric field strength in this case is referred to as a coercive electric field.

Barium titanate has a relatively low value of the coercive electric field, and when a voltage in a range including an electric field close to the coercive electric field or an electric field of the coercive electric field or larger is applied, the polarization may be decreased or reversed.

Therefore, U.S. Patent Application Publication No. 2006/049715 proposes a method of driving a piezoelectric device in which a bias electric field is applied in addition to an alternating electric field so that polarization inversion hardly occur, and further a pseudo-polarization processing is performed during driving so that a decrease of the polarization is reduced.

However, in both the lead-based piezoelectric material and the non-lead-based piezoelectric material, the coercive electric field of the piezoelectric material has temperature characteristics, in which the coercive electric field is decreased along with temperature rise so that the polarization inversion is easily generated. In particular, the non-lead-based piezoelectric material significantly changes its easiness of the polarization inversion at temperature lower than the lead-based piezoelectric material. Therefore, if a uniform bias electric field is set so that an absolute value of the maximum electric field to be applied in the opposite direction to the polarization of the piezoelectric material of a non-lead-based material such as barium titanate is smaller than the coercive electric field of the piezoelectric material at the room temperature, the polarization may be significantly decreased or may be reversed on the high temperature side in which the coercive electric field is decreased compared with the room temperature. On the other hand, if a high bias electric field is set corresponding to the coercive electric field on the high temperature side, an excessive bias electric field is applied on a relatively low temperature in which the coercive electric field becomes relatively large. Therefore, circuit elements having high withstand voltage are necessary. In addition, there is a problem in that if the piezoelectric material has a phase transition temperature at temperature close to the room temperature, there is a steep change of piezoelectric characteristics due to phase transition, and hence a slight change of temperature causes a large deviation of a real displacement from a desired displacement.

### SUMMARY OF THE INVENTION

In view of the above-mentioned problem, an object of the present invention is to provide a method of driving a piezoelectric device capable of using circuit elements having low withstand voltage by suppressing a steep decrease or inversion of polarization of the piezoelectric material by applying a minimal and necessary bias electric field, and of obtaining a desired displacement even if temperature changes.

According to the present invention, there is provided a method of driving a piezoelectric device to generate oscillation in the piezoelectric device, the piezoelectric device including a piezoelectric material having at least two phase transition temperatures and is polarized in a thickness direction, and electrodes disposed on both end surfaces of the piezoelectric material in a direction orthogonal to the polarized direction, the method including: applying an alternating electric field to the piezoelectric device by electric field applying unit; and applying a bias electric field in accordance with a variation of a coercive electric field due to temperature variation so that an absolute value of an electric field in a direction opposite to the polarized direction in the alternating electric field applied by the electric field applying unit becomes smaller than the coercive electric field and so that a polarization of the piezoelectric material is not reversed by the electric field in the direction opposite to the polarized direction.

According to the present invention, it is possible to realize a method of driving a piezoelectric device capable of using circuit elements having low withstand voltage by suppressing a steep decrease or inversion of polarization of the piezoelectric material by applying a minimal and necessary bias electric field, and of obtaining a desired displacement even if temperature changes.

Further features of the present invention will become apparent from the following description of exemplary embodiments with reference to the attached drawings.

### BRIEF DESCRIPTION OF THE DRAWINGS

FIG. 1 is a diagram of a piezoelectric device using a single sheet piezoelectric material according to an example of the present invention.

FIG. 2 is a diagram of a piezoelectric device using a laminated piezoelectric material according to an example of the present invention.

FIG. 3 is a graph illustrating a relationship among temperature of the piezoelectric device, a piezoelectric constant, and an alternating electric field to be applied according to an example of the present invention.

FIG. 4 is a graph illustrating a relationship between electric fields to be applied at room temperature and at high temperature in this example.

FIG. 5 is a graph illustrating a relationship among temperature, a coercive electric field, and a bias electric field to be applied in this example.

### DESCRIPTION OF THE EMBODIMENTS

An embodiment of the present invention is described with reference to the following example.

In the present invention, the phrase “a steep decrease or an inversion of polarization of a piezoelectric material” means that, when a certain electric field is applied to the piezoelectric material, a displacement of the piezoelectric material is steeply decreased or becomes substantially zero so as to decrease in its function or not to function substantially as a piezoelectric material.

### Example

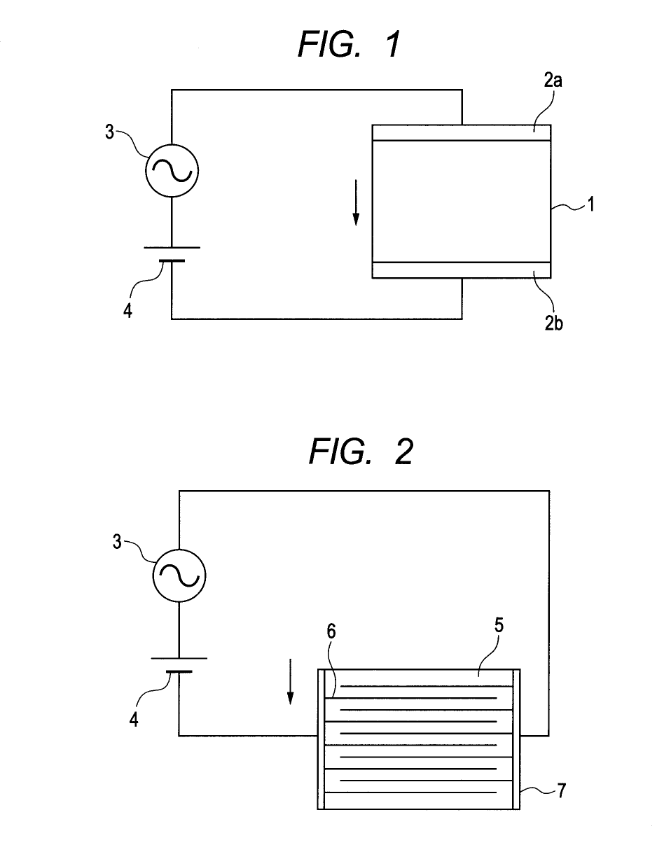

FIG. 1 is a diagram illustrating a method of driving a piezoelectric device including a piezoelectric material having two or more phase transition temperatures in an example of the present invention and is polarized in one of thickness directions, and electrodes disposed on both end surfaces of the piezoelectric material in a direction orthogonal to the polarized direction.

Then, the piezoelectric device of this example is constituted so as to generate oscillation when an alternating electric field is applied by electric field applying unit.

In addition, as illustrated in FIG. 1, a piezoelectric material 1 is polarized in an arrow direction of the diagram (in one of thickness directions).

In this example, the piezoelectric material 1 is a non-lead piezoelectric material that contains barium titanate as a main component but contains no lead.

In addition, electrodes 2a and 2b are disposed on both end surfaces in the direction perpendicular to this polarization direction. The electrodes 2a and 2b are made of a conductive material containing silver as a main component, for example, and are formed by a screen printing method. Further, a DC power source 4 and an AC power source 3 are disposed between the electrodes 2a and 2b.

Here, the piezoelectric device may be a piezoelectric device using a single sheet piezoelectric material or a laminated type piezoelectric device constituted of a piezoelectric material layer 5, an internal electrode 6, and an external electrode 7 as illustrated in FIG. 2.

Barium titanate changes its crystal structure from an orthorhombic to a tetragonal around room temperature when changing from low temperature to high temperature. Therefore, at the temperature as the maximum point, the piezoelectric constant has a steep dependency on temperature. Therefore, a slight change of temperature causes a large change of displacement.

In general, an oscillation displacement of the piezoelectric resonator is proportional to a product of the piezoelectric constant and an applied voltage.

Therefore, when the piezoelectric constant of the piezoelectric material at a certain temperature t is denoted by d(t), an amplitude (0 to peak value) of the alternating electric field to be applied to the piezoelectric material is denoted by V_{AC}(t), and a proportional coefficient is denoted by A, then a displacement x at the temperature t can be expressed as follows.

x=A×d(t)×V_{AC}(t)

Therefore, if the piezoelectric constant d(t) is known, a predetermined displacement x can be obtained by detecting temperature of the piezoelectric material and by setting the amplitude of the alternating electric field in accordance with the temperature so as to satisfy the following relational expression.

V_{AC}(t)=x/(A×d(t))

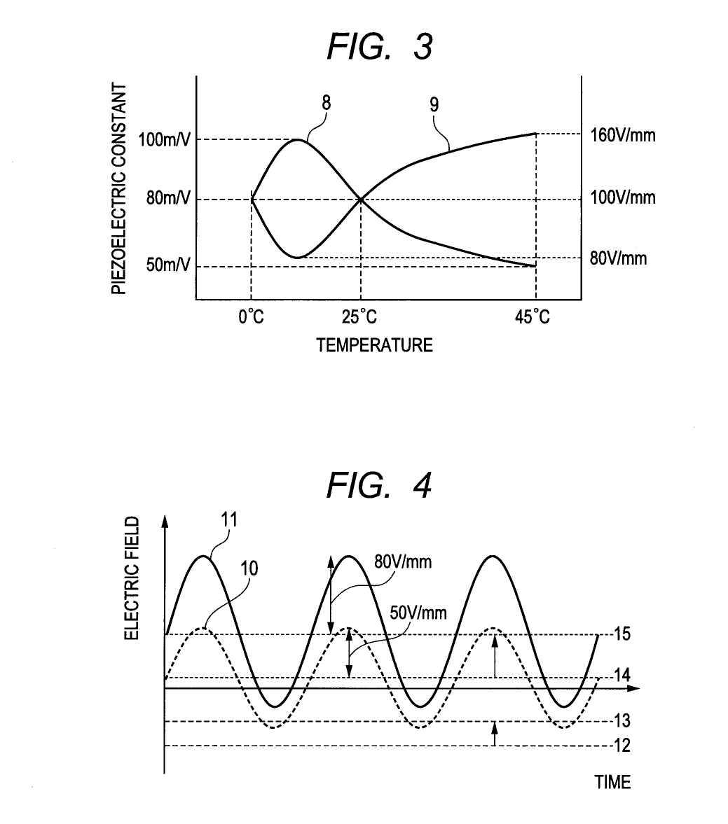

FIG. 3 is a graph illustrating a relationship among temperature of the piezoelectric device 1, a piezoelectric constant 8 of the same, and an alternating electric field 9 to be applied.

The horizontal axis represents temperature, and the vertical axis represents the piezoelectric constant and the electric field. By applying the electric field 9 of the AC component having an amplitude that is inversely proportional to the piezoelectric constant 8 in the method of determining the applied voltage, the displacement can be maintained to be substantially constant even if the temperature changes and the piezoelectric constant is changed.

For instance, it is supposed that necessary amplitude is 8 A. Because the piezoelectric constant is 80 m/V at 25° C., the necessary amplitude V_{AC}(t) of the alternating electric field is set to 100 V/mm.

In addition, because the piezoelectric constant is decreased to 50 m/V at 45° C., the necessary amplitude V_{AC}(t) of the alternating electric field is set to 160 V/mm.

As temperature of the piezoelectric material rises to be closer to the Curie temperature, the coercive electric field that reverses the polarization is decreased by the electric field having the opposite direction to the polarization direction and a predetermined strength or larger, and hence the polarization can be reversed easily.

In particular, because the barium titanate-based piezoelectric material has the Curie temperature around 130° C., this degree is large.

Therefore, when the coercive electric field at the certain temperature t is denoted by Ec(t), an amplitude of the alternating electric field in the direction opposite to the polarized direction to be applied to the piezoelectric material is denoted by V_{AC}(t), and an absolute value of the DC electric field to be applied as a bias electric field in the same direction as the polarization of the piezoelectric material is denoted by V_{DC}(t), then V_{DC}(t) is set so that the following relational expression is satisfied.

Ec(t)>V_{AC}(t)−V_{DC}(t)

Thus, the polarization inversion can be suppressed by applying a minimal and necessary bias electric field.

FIG. 4 is a graph illustrating a relationship of the electric fields to be applied at room temperature and at high temperature in this example. The horizontal axis represents time, and the vertical axis represents the electric field.

The up direction of FIG. 4 corresponds to the electric field in the same direction as the polarization.

In the above-mentioned method of determining V_{DC}(t), by applying a bias electric field 14 (10 V/mm) at a temperature near 25° C., an applied electric field is set as denoted by 10 so that an absolute value of the maximum electric field in the direction opposite to the polarization is smaller than a coercive electric field 12 (50 V/mm) at this temperature.

Thus, the polarization inversion is suppressed. In addition, if the temperature rises to 45° C., the coercive electric field is decreased as denoted by 13 (30 V/mm). In this case, in order to compensate the decrease of the piezoelectric constant, the amplitude V_{AC}(t) of the alternating electric field is set to be large. Therefore, by applying a bias electric field 15 (60 V/mm) that is larger than that at 25° C., the applied electric field is set as denoted by 11 so that the polarization inversion is suppressed in the same manner.

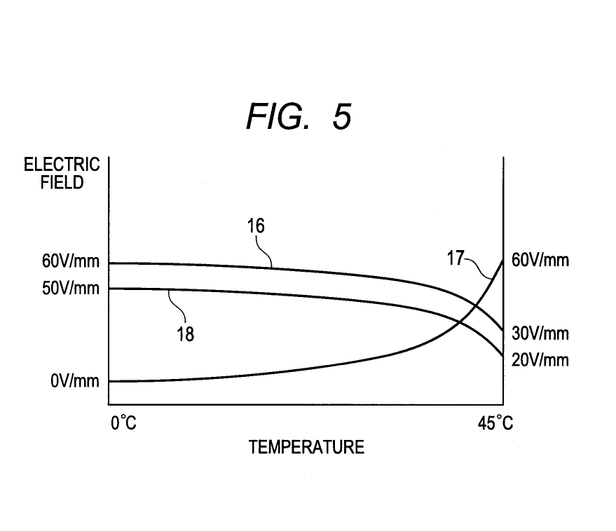

FIG. 5 is a graph illustrating a relationship of temperature, a coercive field, and the bias electric field to be applied in this example.

The horizontal axis represents temperature, and the vertical axis represents the electric field. By the above-mentioned method of determining V_{DC}(t), if the temperature rises from 0° C. to 45° C., a coercive electric field 16 is decreased from 60 V/mm to 30 V/mm.

A bias electric field 17 is applied so that an absolute value 18 of the maximum electric field in the direction opposite to the polarization becomes smaller than the coercive electric field 16. In this method, by applying the bias electric field when the coercive electric field is decreased along with temperature rise, the polarization inversion can be suppressed. Ideally, it is preferred that the period for applying the bias electric field 17 be set so that the absolute value 18 of the maximum electric field in the direction opposite to the polarization is smaller than the coercive electric field 16. However, the property is not necessarily that the polarization is reversed when the coercive electric field is exceeded even for a moment. Therefore, there may be a moment while the absolute value 18 of the maximum electric field in the direction opposite to the polarization exceeds the coercive electric field 16 in the range that does not decrease significantly or reverse the polarization. For instance, in order to reduce power consumption or to secure flexibility of design such as use of a simple control circuit, the bias electric field 17 may be applied in an intermittent manner.

In addition, by suppressing application of excessive bias electric field at low temperature, circuit elements having low withstand voltage can be used.

As mentioned above, according to the structure of this example, it is possible to apply the bias electric field in accordance with a variation of the coercive electric field due to temperature variation so that the absolute value of the electric field in the direction opposite to the polarized direction in the alternating electric field becomes smaller than the coercive electric field.

In addition, also in the case where the amplitude of the alternating electric field is increased to obtain a desired displacement besides the decrease of the coercive electric field due to the temperature rise, the steep decrease or inversion of the polarization can be suppressed by determining the bias electric field by the same method.

The main component of the piezoelectric material constituting the piezoelectric device in this example is not limited to barium titanate.

The piezoelectric material needs to have two or more phase transition temperatures, and its main component may be, for example, potassium niobate, potassium-sodium niobate, or the like.

Also in the method of driving the piezoelectric device using the above-mentioned piezoelectric material, the steep decrease or inversion of the polarization can be suppressed while a desired displacement can be obtained by the same method as described above.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-287491, filed Dec. 24, 2010, which is hereby incorporated by reference herein in its entirety.

What is claimed is:

1. A method of driving a piezoelectric device to generate oscillation in the piezoelectric device, the piezoelectric device including a piezoelectric material having at least two phase transition temperatures and is polarized in a thickness direction, and electrodes disposed on both end surfaces of the piezoelectric material in a direction orthogonal to the polarized direction, the method comprising:
applying an alternating electric field to the piezoelectric device by electric field applying unit; and
applying a bias electric field in accordance with a variation of a coercive electric field due to temperature variation so that an absolute value of an electric field in a direction opposite to the polarized direction in the alternating electric field applied by the electric field applying unit becomes smaller than the coercive electric field and so that a polarization of the piezoelectric material is not reversed by the electric field in the direction opposite to the polarized direction.

2. The method of driving a piezoelectric device according to claim 1, wherein, when a coercive electric field at a certain temperature t of the coercive electric field is denoted by Ec(t), an amplitude of the alternating electric field in the direction opposite to the polarized direction at the certain temperature t is denoted by V_{AC}(t), and an absolute value of a DC electric field to be applied as the bias electric field in the same direction as the polarized direction is denoted by V_{DC}(t), then V_{DC}(t) is set so that the relational expression Ec(t)>V_{AC}(t)−V_{DC}(t) is satisfied.

3. The method of driving a piezoelectric device according to claim 2, wherein, when a piezoelectric constant at the certain temperature t of the piezoelectric material is denoted by d(t), and a proportional coefficient is denoted by A, then a predetermined displacement is obtained by setting the amplitude V_{AC}(t) depending on the temperature so that the relational expression V_{AC}(t)=x/(A×d(t)) is satisfied.

4. The method of driving a piezoelectric device according to claim 1, wherein the piezoelectric material comprises one of barium titanate, potassium niobate, and potassium-sodium niobate as a main component.
